(19) United States
(12) Patent Application Publication
(10) Pub. No.: US 2007/0044914 A1
(43) Pub. Date: Mar. 1, 2007

(54) Vacuum processing apparatus

(76) Inventors: Katsuji Matano, Kudamatsu (JP); Muneo Furuse, Kudamatsu (JP); Takashi Fujii, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/213,735

(22) Filed: Aug. 30, 2005

(51) Int. Cl. H01L 21/306

(52) U.S. Cl. 156/345.24

(57) ABSTRACT

A vacuum processing apparatus for plasma processing a sample, by controlling the temperature distribution, the RF bias and the electrostatic adsorption bias of the sample table, wherein the sample table comprises a plurality of sample table blocks (first, second, third, and nth sample table blocks) divided from the sample table circumferentially, that is, coaxially or radially into a plurality of portions each in a structure independent electrically and heat conductively, and each of the sample table blocks has a unit for conducting independent control for each of the temperature, the RF bias, or the pressure at the wafer rear face of the wafer.

### FIELD OF THE INVENTION

The present invention concerns a vacuum processing apparatus and, particularly, it relates to a vacuum processing apparatus having a plurality of sample tables.

### BACKGROUND OF THE INVENTION

In the processing of samples by using plasmas, unevenness of the processing within the plane of wafers has resulted in a problem because of unevenness in the processing factors such as the temperature distribution, the distribution of the plasma density, the distribution of reaction products, etc on a processing table. As one of means for solving such a problem it has been proposed control for the temperature distribution within the plane of wafers.

For example, for the control of the temperature of the sample table, Japanese Patent Laid-Open No. H8(1996)-45909 describes that a sample table is divided into plural temperature control blocks, such that temperature can be controlled for the circumference and the central portion of the sample table independently to form a desired temperature distribution to the surface where wafers are closely bonded and secured.

Further, Japanese Patent Laid-Open No. 2002-9043 describes that a sample table for holding a wafer is divided into plural electrodes, the divided electrodes of the sample table are electrically separated from each other by an insulator and different electric power is supplied to each of the divided electrodes thereby controlling the etching rate for the circumference and the central portion of the sample table.

Further, Japanese Patent Laid-Open No. 2003-243380 describes that slits for flowing coolants are disposed independently for the inner circumference and the outer circumference in an electrode block of an integrated structure as a sample table, so that temperature can be controlled independently for the circumference and the central portion of the sample table.

In the example described in Japanese Patent Laid-Open No. H8(1996)-45909, since the sample table is divided into plural temperature control blocks, an abrupt temperature difference is caused at the boundary of division when coolants at different temperatures are caused to flow to possibly result in undesired effects on the wafer processing. Further, in the vacuum processing of a sample, while the processing performance can not be improved unless both reaction products and ions in plasmas are controlled accurately by the temperature control, since they are not taken into consideration in this literature, it involves a problem that a processing performance at high accuracy is difficult to obtain.

In the example of Japanese Patent Laid-Open No. 2002-9043, while the processing performance can not be improved unless the reaction products in the plasmas are also controlled accurately, since no consideration is taken to a case of dividing the sample table into plural electrodes, it involves a problem that the highly accurate processing performance is difficult to obtain.

In the example of Japanese Patent Laid-Open No. 2003-243380, while the temperature distribution of the sample table is controlled by flowing coolants of different temperatures to the electrode slits for inner circumference and outer circumference respectively, since the sample table has an integrated structure, it involves a problem that highly accurate temperature control is difficult by the heat conduction of respective coolants.

Then, even when the existent techniques described above are combined to each other, since no consideration are taken regarding the control of the pressure at the rear face of the wafer by electrostatic adsorption bias, it involves a problem that highly accurate temperature control for the sample table is difficult.

Then, in any of the existent techniques described above, CD loss as a result of the most important shape controllability in the current processing performance is about 3 nm, and this results in a significant problem that the CD loss can be reduced no more.

Further, no sufficient consideration are taken for controlling and setting the conditions in the radial direction within the plane of the wafer appropriately and rapidly corresponding to various characteristics.

### SUMMARY

In order to overcome the foregoing problems and conduct uniform processing of samples accurately, the present invention intends to provide a vacuum processing apparatus capable of attaining high production efficiency and high product yield, for example, by improving the current CD loss so as to be decreased from about 3 nm to about 1 nm in the processing performance, by accurately controlling the temperature distribution, and RF bias and electrostatic adsorption bias distribution within the plane of the sample.

### SUMMARY OF THE INVENTION

For attaining the foregoing object in accordance with a feature of the present invention, in a control method for the temperature distribution, the RF bias and the electrostatic adsorption bias for a sample table for a processing apparatus for plasma processing of a sample, the sample table comprises a plurality of sample table blocks (first sample table block, a second sample table block, and an nth sample table block) formed by dividing the sample table circumferentially, that is, concentrically or radially into a plurality of portions and each of the sample table blocks has a unit of conducting independent control for the temperature, the RF bias, the electrostatic adsorption bias, and the pressure at the rear face of the wafer, each of a structure electrically or heat conductively independent of each other.

According to the invention, optimal control for the temperature distribution, the RF bias distribution, and the electrostatic adsorption bias distribution can be conducted independently to the first sample table block for the central portion of the sample and the second sample table block for the outer circumference of the sample respectively in accordance with the device pattern of the plasma-processed sample in view of the plurality of sample table blocks.

Accordingly, vacuum processing method and apparatus capable of attaining high production efficiency and high product yield can be provided since the sample can be processed uniformly at high accuracy.

According to the invention, since all kinds of wafers can be processed uniformly at high accuracy, it is possible to provide a vacuum processing apparatus capable of attaining high production efficiency and high product yield.

### BRIEF DESCRIPTION OF THE DRAWINGS

Preferred embodiments of the present invention will be described in details based on the drawings, wherein

FIG. 1 is a schematic cross sectional view of a vacuum processing apparatus as a preferred embodiment according to the present invention;

FIG. 2 is a plan view of a sample table in a preferred embodiment of the invention;

FIG. 3 is a plan view of a sample table in a preferred embodiment of the invention;

FIG. 4 is a plan view of a sample table in a preferred embodiment of the invention;

FIG. 5 is a plan view of a sample table in a preferred embodiment of the invention;

FIG. 6 is a plan view of a sample table in a preferred embodiment of the invention;

FIG. 7 is a plan view of a sample table in a preferred embodiment of the invention;

FIG. 8 is a schematic view for a preferred embodiment (reaction product control) of the invention;

FIG. 9 is a schematic view for a preferred embodiment (plasma/ion control) of the invention;

FIG. 10 is a schematic view for a preferred embodiment (wafer rear face pressure control) of the invention;

FIG. 11 is a schematic view for a preferred embodiment (etching temperature control) of the invention; and

FIG. 12 is a schematic view for a preferred embodiment (etching temperature control) of the invention.

### DETAILED DESCRIPTION OF THE PREFERRED EMBODIMENTS

### EXAMPLE 1

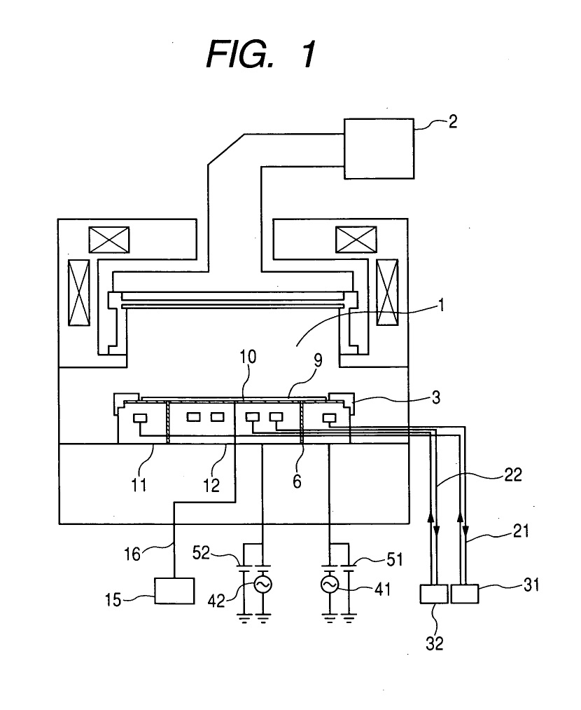

A basic constitutional view of the present invention is shown in FIG. 1. An embodiment of the invention is to be described for a bisected sample table 10 with reference to FIG. 2.

As sample table 10 has a first sample table block 11 and a second sample table block 12 bisected circumferentially, that is, coaxially each in an independent structure. Each of the sample table blocks 11 and 12 has a unit for conducting independent control for each of the temperature, the RF bias, the electrostatic adsorption bias, and the pressure at the rear face of the wafer.

That is, a first coolant channel 21 is disposed to the outer circumference in the sample table 10, and a second coolant channel 22 is disposed to the inside thereof. The first coolant channel 21 is connected at one end by way of a flow channel to a temperature control device 31, while the second coolant channel 22 is connected at the other end by way of a flow channel to a temperature control device 32. Not illustrated tank and pump are disposed to each of the temperature control devices 31 and 32 and the coolant is controlled for the temperature in the tank and circulated by the pump.

With the constitution described above, the coolant controlled for the temperature in the tank is introduced into the first coolant channel 21 and flows through the first coolant channel 21 to thereby cool the outer circumference of the sample table 10, that is, the first sample table block 11 to an optical temperature. Further, the coolant flows through the second coolant channel 22 to thereby cool the central portion of the sample table 10, that is, the sample table block 12 to an optimal different temperature. The coolant going out of the second coolant channel 22 is again cooled to an optimal temperature by a cooling device of the temperature control device 32 and then exits from the temperature control device 32 and cools the second sample table block 12 to an optimal temperature by way of the second coolant channel 22. The situation is identical also for the first coolant.

As described above, the coolants introduced in the sample table 10 pass predetermined route and changed for the temperature by the temperature control devices 31 and 32 and then again introduced into the sample table 10. Due to the temperature difference between the first sample table block 11 and the second sample table block 12 in this case, an optimal temperature distribution is formed on the surface of the sample table 10.

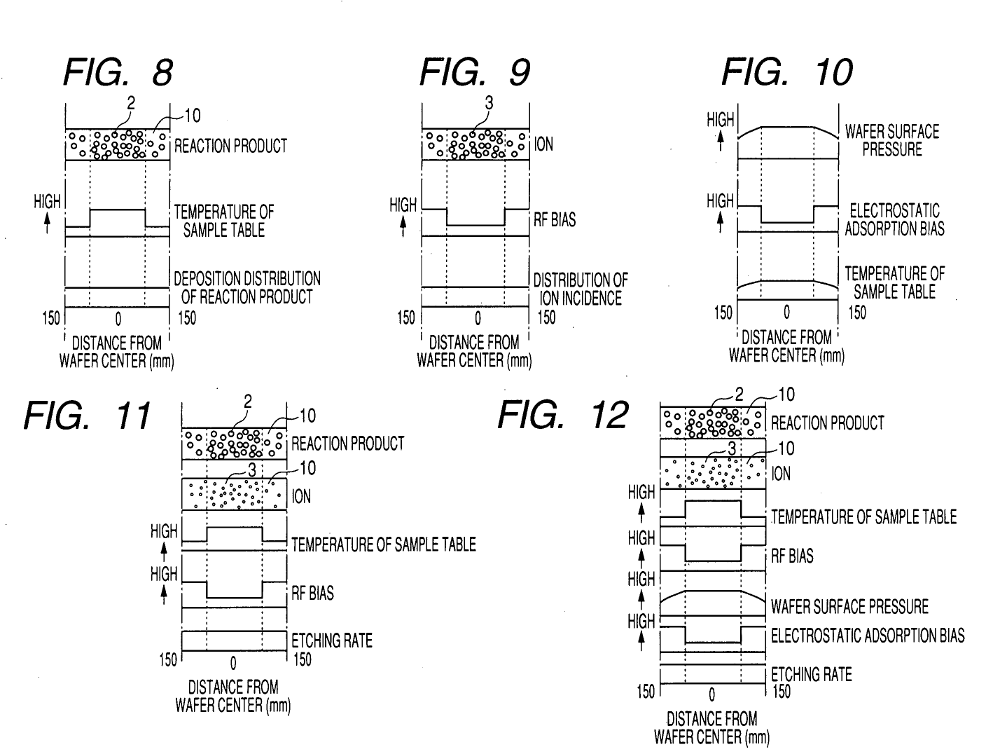

In the setting for the distribution of the surface temperature of the sample table 10 constituted as described above, the temperature distribution is adjusted, for example, as shown in FIG. 8 conforming the distribution for the formation of reaction products during plasma processing for the wafer 9. That is, the sample temperature is set higher for a portion where more reaction products are present to suppress re-deposition of the reaction products thereby unifying the processing speed for the entire wafer 9.

In a case where the distribution for the formation of reaction products upon plasma-etching of the wafer 9 is such that more reaction products are formed in the central portion of the wafer 9, which are gradually decreased toward the circumference of the wafer 9 as an example, the temperature distribution for the wafer 9 to be put to plasma processing is set in accordance with the distribution of the reaction products. Accordingly, the temperature distribution for the holding surface of the wafer 9 of the sample table 10 is set such that the temperature is higher for the central portion and gradually lowers toward the outer circumference of the wafer 9.

In order to obtain such a temperature distribution, in this example, the second coolant channel 22 is disposed corresponding to a range for the central portion where the temperature is higher and the first coolant channel 21 is disposed to a portion corresponding to the outside of the outer circumference of the wafer 9. Since the second coolant channel 22 and the first coolant channel 21 are completely insulated by a shielding layer 6 heat conductively and electrically, an optimal temperature gradient is formed from the central portion where the temperature is higher to the circumference, so that temperature control can be attained.

According to this example, the sample table 10 has the first sample table block 11 and the second sample table block 12 each into a structure independently of each other formed by coaxially bisecting the sample table 10. Since each of the sample table blocks has a function of conducting control for temperature, pressure, etc. independently, the reaction products 2 on the wafer 9 can be distributed accurately and uniformly by forming an optimal temperature distribution in accordance with the film specification of the respective wafers 9 to be processed to the sample placing surface of the sample table 10.

### EXAMPLE 2

Then, the sample table 10 using the basic constitution described above in FIG. 1 is applied to a plasma etching apparatus and an example thereof is to be described with reference to FIG. 1. A processing chamber 1 has a sample table 10 for placing a sample, for example, a wafer 9 as a work at the inside thereof. In this example, the sample table 10 has a sample table 10 in which a surface for placing the wafer 9 is formed and fabricated with grooves for a coolant flow channel, a first sample table block 11 at the outer circumference of the wafer 9 for forming a coolant channel covering the grooves, a second sample table block 12 for the central portion, a cover 3 covering the lateral side and the upper surface of the sample table 10, and an electrode support shaft (not illustrated) for supporting an electrode. A vacuum atmosphere is kept in the processing chamber 1. A processing gas is supplied from a processing gas introduction port (not illustrated) into the processing chamber 1. Further, inside of the processing chamber 1 is exhausted by a vacuum pump (not illustrated), which is connected to an exhaustion lo port (not illustrated). A plasma generation source 7 generates plasmas in the processing chamber 1. A heat conduction gas supply channel 16 in communication with the surface for placing the wafer 9 of the sample table 10 is formed in the electrode support shaft to which a heat conduction gas supply source 15 is connected. The heat conduction gas is, for example, an He gas and the amount of supply is controlled by a heat conduction gas pressure control system (not illustrated) such that the pressure of the heat conduction gas between the rear face of the wafer 9 and the sample table 10 is at a predetermined value. Further, first and second RF power sources 41 and 42 for giving incident energy to ions in the plasmas and first and second DC power sources 51 and 52 for electrostatically adsorbing the wafer 9 onto the sample table 10 are connected to the first and the second sample table blocks 11 and 12. The sample table 10 is made of a material such as aluminum or titanium and a flame-sprayed film such as of alumina ceramics is formed to the upper surface to form a dielectric film for electrostatic adsorption.

The coolant supply by using the temperature control devices 31 and 32 for conducting temperature control of the sample table 10 is based on the basic constitution described above for which duplicate description is to be omitted.

The plasma generation source includes, for example, a capacitance coupling system, an induction coupling system, or an ECR system using microwaves or UHF waves and the invention is not restricted by the plasma generation method.

According to the example, it is possible to control the optimal temperature distribution (coolant temperature, He pressure), the RF bias, distribution, and the electrostatic adsorption bias distribution individually to the first sample table block for the central portion of the sample and the sample table block for the outer circumference of the sample to a plurality of sample table blocks formed each in an independent structure in accordance with the device pattern of the sample to be put to plasma processing.

Accordingly, since the sample can be processed uniformly at high accuracy, it is possible to provide vacuum processing method and apparatus capable of attaining high production efficiency and high product yield.

### EXAMPLE 3

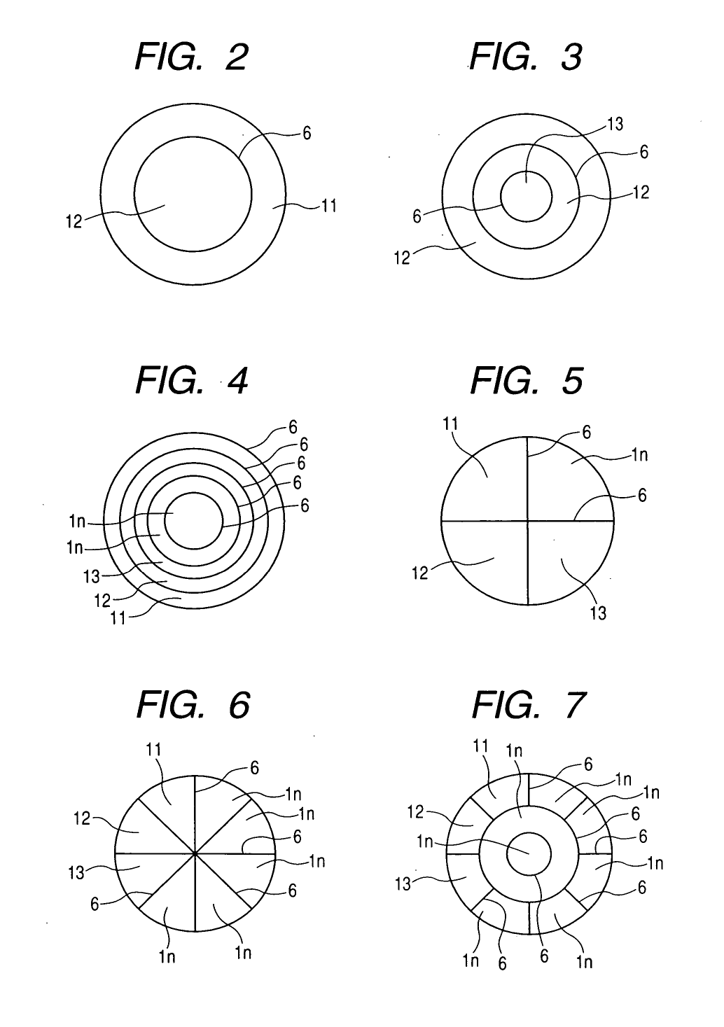

The invention enables to conduct each control for the temperature, the RF bias, and the pressure at the rear face of the wafer at high accuracy to a plurality of sample table blocks (first, second, third, and nₜₕ sample table blocks) formed by dividing the sample table circumferentially, that is, coaxially or radially into plural independent structures individually. The invention is applicable also to any of the sample tables 10, for example, shown in FIG. 3 to FIG. 7 as divided sample table blocks.

In the example of FIG. 3, a sample table has first, second, and third sample table blocks 11, 12, and 13 each of an independent structure divided circumferentially, that is, coaxially from a sample table, in which the sample table blocks are completely insulated from each other heat conductively and electrically by shield layers 6.

In the example of FIG. 4, a sample table has first, second and third sample table blocks 11, 12, 13, n1, and n each of an independent structure divided into n portion, for example, five portions, circumferentially, that is, coaxially from a sample table, in which the sample table blocks are completely insulated from each other heat conductively and electrically by shield layers 6.

In the example of FIG. 5, a sample table has first, second, and third sample table blocks 11, 12, 13, and n1 each of an independent structure divided into n portion, for example, four portions, circumferentially, that is, radially from a sample table, in which the sample table blocks are completely insulated from each other heat conductively and electrically by shield layers 6.

In the example of FIG. 6, a sample table has first, second and third sample table blocks 11, 12, 13, - - - and n1 each of an independent structure divided into n portion, for example, eight portions, circumferentially, that is, radially from a sample table, in which the sample table blocks are completely insulated from each other heat conductively and electrically by shield layers 6.

In the example of FIG. 7, a sample table has first, second and third sample table blocks 11, 12, and 13 each of an independent structure divided into first, second, and third three portions circumferentially, that is, coaxially from a sample table, in which the sample table blocks are completely insulated from each other heat conductively and electrically by shield layers 6. Further, the sample table block at the outermost circumference has sample table blocks 11, 12, 13, and n1 each of an independent structure divided into n portions, for example, eight portions, circumferentially, that is, radially from a sample table, in which the sample table blocks are completely insulated from each other heat conductively and electrically by shield layers 6.

### EXAMPLE 4

An etching processing for Al wiring-films using the plasma etching apparatus described above is to be described as an example. Description is to be made to a case applied to the sample table 10 of the example shown in FIG. 1. FIG. 8 schematically shows the control system of Example 4. FIG. 8 also shows the distribution of reaction products 2 formed by plasma-etching.

The sample table 10 has coaxially bisected first sample table block 11 and second sample table block 12. Each of the sample table blocks 11 and 12 has a function of controlling temperature individually.

At first, a mixed gas of BCl₃/Cl₂ is introduced as a processing gas from a processing gas supply port at a predetermined flowing amount into the processing chamber 1 and, at the same time, the inside of the chamber is evacuated by a vacuum pump to keep the processing pressure at 2 Pa. Then, the processing gas in the processing chamber is formed into plasmas by using a micro ECR source as a plasma generation source 2. In this case, the gas flow caused by evacuation is preferably discharged downward of the sample table and exhausted uniformly at the circumference of the sample table.

Further, the temperature of the coolant flowing in the first coolant channel 21 of the first sample table block 11 is set by a temperature control device 31 such that the temperature at the circumference of the wafer 10 is 20° C. and the temperature of the coolant flowing in the second coolant channel 22 of the second sample table block 12 is set by the temperature control device 32 such that temperature at the central portion of the wafer is 60° C. in the sample table 10. Thus, temperature difference of 40° C. is set between the central portion and the outer circumference of the wafer 9. The range for the temperature of 60° C. for the central portion of the wafer 9 is set to about ⅓ of the wafer diameter.

The wafer 9 is placed on the sample table 10 for which the temperature is set as described above and held by electrostatic adsorption, and an He gas is supplied from the heat conduction gas supply channel 16. The electrostatic adsorption device adsorbs the wafer electrostatically for the entire circumference such that leakage of the He gas from the outer circumference of the wafer is suppressed and also partially adsorbs the wafer such that the central portion of the wafer 9 is prevented from rising due to the pressure of the heat conduction gas. This can cool the wafer 9 in accordance with the temperature distribution formed to the sample table 10.

The wafer 9 is formed of a wiring film formed by stacking an Al alloy and a TiN barrier metal and a patterned resist film. In a case of etching process under the conditions described above, the CD loss at the central portion and the outer circumference of the wafer can be improved greatly compared with the case of not providing the temperature difference to the sample table 10 in view of the past processing actual performance. Further, this is particularly effective, for example, in a case of gate material etching that gives a significant effect on the yield upon processing the wafer 9.

This example shows an effect in a case where the sample table 10 is bisected but this is applicable also to other sample tables 10 shown in FIG. 3 to FIG. 7.

For example, it will be apparent that as the sample table 10 is further divided to decrease the area, the CD loss upon processing of wafer 9 is further decreased to increase the yield. That is, according to the invention, an optimal distribution of the reaction products 2 can be obtained by controlling the temperature distribution for a portion of the wafer (sample table) 9 accurately and uniformly.

The reaction products formed by plasma etching are distributed such that more reaction products are present for the central portion of the wafer 9, which are decreased at the outer circumference of the wafer 9 for example due to the distribution of the plasma density caused by the generation of plasmas, flow of vacuum exhaustion, etc. Since an optimal temperature difference is formed between the first sample table block 11 for the central portion of the wafer 9 and the second sample table block 12 for the outer circumference of the wafer 9 conforming the distribution of the reaction products, the temperature is higher for the wafer 9 at the central portion where more reaction products are present thereby capable of suppressing re-deposition of the reaction products and suppressing the increase of the CD loss.

Further, since the temperature of the wafer 9 is lowered in accordance with the decrease for the amount of the reaction products over the outer circumference of the wafer 9, that is, the second sample table block 12, the wafer temperature lowers along with gradual decrease of the re-deposition amount of the reaction products to increase the probability for the re-deposition of the reaction products thereby enabling to attain the same extent of the CD loss as in the central portion of the wafer at high accuracy.

This can decrease and improve the CD loss in the wafer surface to improve the processing performance. This method is particularly effective in a case where the formed pattern has varied density.

### EXAMPLE 5

In the same manner as for the temperature distribution described above, an optimal RF bias distribution can also be formed in accordance with the film specification of each of the wafers 9 processed at the sample placing surface of the sample table 10. Description is to be made to a case applied to the sample table 10 of the example shown in FIG. 1. FIG. 9 schematically shows the control system of Example 5. FIG. 9 also shows the distribution of plasma (ion) 3.

The sample table 10 has coaxially bisected first sample table block 11 and second sample table block 12. Each of the sample table blocks 11 and 12 has a unit of controlling the RF bias individually.

In the process for manufacturing the semiconductor device, wafer 9 is placed on the sample table 10, an etching gas is supplied to a space over the wafer 9, the gas supplied to the space over the wafer 9 is formed into plasmas, electric power is supplied to the sample table 10 to conduct chemical reaction between the gas of the plasmas and the surface of the semiconductor wafer 9 thereby etching the wafer 9. The wafer 9 is placed on the sample table 10 divided into two sample table blocks, and the RF bias applied near the outer circumference of the first sample table block and the RF bias applied near the central portion of the second sample table 6 can be controlled accurately.

Since the plasma is not generally uniform over the wafer 9 in the processing chamber 1 but the density is higher in near the central portion of the wafer 9 compared with that at the circumference of the wafer 9, in a case where RF bias is applied uniformly as in the existent case of an integrated type sample table 10, the etching speed becomes different between the central portion and the outer circumference of the wafer 9 (micro-loading effect), which results in poor shape or increase in the CD loss to lower the yield.

In view of the above, in the invention, an RF bias is applied accurately and uniformly to each of the first sample table block 11 and the second sample table block 12 in accordance with the state of plasmas over the wafer 9 and the semiconductor device pattern (such as varied density), by which the etching rate within the plane of the wafer 9 can be controlled accurately to improve the yield.

In the general example described above, since the density of the plasma 3 is higher near the central portion of the wafer 9 compared with that in the circumference of the wafer 9, the plasma/ion within the plane of the wafer 9 can be unified simply by decreasing the RF bias for the second sample table block 12 in the central portion of the wafer 9 compared with the RF bias for the first sample block 11 at the outer circumference of the wafer 9. Further, it will be apparent that in a case where the state of plasmas in the processing chamber 1 is in a opposite state, that is, the density of the plasmas is higher near the circumference of the wafer than that near the central portion of the wafer 9, processing can be conducted in the manner opposite to that described above.

According to the invention, optimal plasma/ion 3 distribution can be obtained by controlling the RF bias accurately and uniformly for a certain portion of the wafer (or sample table 9).

It will be apparent that the invention is applicable also to other sample tables 10 shown in FIG. 3 to FIG. 7.

### EXAMPLE 6

Further, in the same manner as for the RF bias distribution described above, it is also possible to form an optimal electrostatic adsorption bias distribution conforming the film specification of the respective wafers 9 processed on the sample placing surface of the sample table 10 and the state of the distribution of the pressure at the rear face of the wafer. Description is to be made to a case applied to the sample table 1 of the example shown in FIG. 1. FIG. 10 schematically shows the control method in this Example 6.

The sample table 10 has coaxially bisected first sample table block 11 and second sample table block 12. Each of the sample table blocks 11 and 12 has a unit of conducting control for electrostatic adsorption bias individually.

In the same manner as described above, in the method of manufacturing a semiconductor device having the step of etching a wafer 9, wafers 9 are placed on a sample table 10 divided into a plurality of sample tables 10 and the electrostatic adsorption bias applied near the outer circumference of the first sample table block 11, and the electrostatic adsorption bias applied near the central portion of the second sample table block 21 can be controlled accurately and uniformly.

In the pressure distribution at the rear face of the wafer 9, since the pressure of the He gas at the outermost circumference of the wafer 9 is higher than the pressure in the processing chamber during plasma formation, the pressure is abruptly lowered at the outer circumference of the wafer 9. That is, the surface temperature at the outer circumference of the wafer 9 is increased to higher than that for the central portion due to the lowering of the pressure of the He gas. Accordingly, since the pressure at the rear face of the wafer 9 can be controlled uniformly between the outer circumference and the central portion of the wafer 9 by pressing the outer circumference of the wafer 9 more intensely than the central portion thereof, that is, by setting the electrostatic adsorption bias for the first sample table block 11 to higher than that for the second sample table block 21 for making the distribution of the setting temperature for the sample table 10 uniform between the central portion and the outer circumference of the wafer 9 by the He gas at the rear face of the wafer 9, the temperature at the surface of the wafer 9 can be easily controlled accurately according to the invention.

Further, along with the increasing trend for the diameter of the wafer 9 in recent years, a problem has been caused in view of the reliability such as adsorption of the wafer 9 or the detaching error during processing of the wafer 9 due to upward and downward deformation of the outer circumference of the wafer 9 by thermal stress or the like during the step of manufacturing the semiconductor device over the wafer 9. Then, since the wafer 9 can be made into a flat state simply by optimizing the electrostatic adsorption bias for the first and the second sample table blocks 11 and 12 depending on the deformation state of the wafer 9 according to the invention, this can contribute also to the improvement of the reliability.

That is, an optimal pressure difference at the rear face of the wafer 9 can be obtained by controlling the electrostatic adsorption bias accurately and uniformly for a certain portion of the wafer (or sample table).

It will be apparent that the invention is applicable in the same manner also to other sample tables 10 shown in FIG. 3 to FIG. 7.

### EXAMPLE 7

Then, highly accurate and uniform etching rate can be obtained by combining the control for the reaction products over the wafer 9 described in Example 4 and the control for the ion distribution described in Example 5.

Description is to be made to a case applied to the sample table 10 of the example in FIG. 1. FIG. 11 schematically shows the control method of Example 7.

The sample table 10 has coaxially bisected first sample block 11 and second sample table block 12. Each of the sample table blocks 11 and 12 has a function of controlling the temperature and a function of controlling the RF bias individually.

It will be apparent that the invention is applicable in the same manner also to other sample tables 10 shown in FIG. 3 to FIG. 7.

### EXAMPLE 8

It will be apparent that highly accurate and uniform etching rate can be obtained by combining the control for the reaction products 2 and the ion distribution over the wafer 9, and the control for the pressure at the rear face of the wafer 9 described above.

Description is to be made to a case applied to the sample table 10 of the example in FIG. 1. FIG. 12 schematically shows the control method of this Example 8.

The sample table 10 has coaxially bisected first sample table block 11 and second sample table block 12. Each of the sample table blocks 11 and 12 has a function of conducting each of the controls for the temperature, the RF bias, and the pressure at the rear face of the wafer individually.

As has been described above, in a case of processing the semiconductor wafer 9, highly accurate processing for the wafer 9 at a CD loss of about 1 nm, etc. compared with the existent case is possible and high production efficiency and high product yield can be attained by optimizing the combination for each of the temperature distribution, the RF bias, and the electrostatic adsorption bias for the sample table accurately and uniformly so as to align the device pattern of the wafer, state of plasmas, pressure distribution at the rear face of the wafer, and the deformation state of the wafer in the processing chamber 1.

It will be apparent that the invention can be applied in the same manner also to other sample tables 10 shown in FIG. 3 to FIG. 7.

While the descriptions have been made to an example of a plasma etching apparatus in each of the examples described above, the invention is applicable generally to processing apparatus where works such as a wafer are processed under heating in a vacuum atmosphere. For example, the processing apparatus utilizing the plasmas include, for example, plasma etching apparatus, plasma CVD apparatus, and sputtering apparatus. Further, processing apparatus not utilizing plasmas include, for example, ion implantation, MBE, vapor deposition, vacuum CVD, etc.

What is claimed is:

1. A vacuum processing apparatus of processing a wafer by etching used for conducting a method of controlling the apparatus, including
an etching gas supplying unit for supplying an etching gas into a vacuum chamber and converting the supplied etching gas into plasmas,
an electrostatically adsorbing unit for electrostatically adsorbing a wafer in the vacuum chamber to a sample table by an electrostatic adsorption power source,
a bias applying unit for applying a bias to the sample by an RF power source, and
a heat conduction gas supplying unit for supplying a heat conduction gas between the rear face of the wafer and a wafer placing surface of the sample table thereby etching the wafer, wherein
the sample table comprises a plurality of sample table blocks divided from the sample table circumferentially, that is, coaxially or radially into a plurality of portions each of an independent structure, and each of the sample table blocks has a unit for conducting independent control for each of the temperature, the RF bias, and the pressure at the rear face of the wafer.

2. A vacuum processing apparatus according to claim 1, wherein a plurality of sample table blocks divided from the sample table circumferentially, that is, coaxially or radially into a plurality of portions each of an independent structure can conduct accurate and uniform control each individually for the temperature, the RF bias, and the like in the divided regions within a plane of the wafer as the number of division increases.

3. A vacuum processing apparatus according to claim 1, wherein the temperature distribution is controlled accurately and uniformly in regions divided into a plurality of portions such as a first sample table block for the central portion of the wafer and a second sample table block for the outer circumference of the wafer in a plurality of sample table blocks divided from the sample table circumferentially, that is, coaxially or radially into a plurality of portions each of an independent structure, conforming the device film specification such as density difference of the wafer put to etching processing and the density distribution of reaction products in the vacuum chamber.

4. A vacuum processing apparatus according to claim 1, wherein the RF bias distribution is controlled accurately and uniformly in regions divided into a plurality of portions such as a first sample table block for the central portion of the wafer and a second sample table block for the outer circumference of the wafer in a plurality of sample table blocks divided from the sample table circumferentially, that is, coaxially or radially into a plurality of portions each of an independent structure, conforming the device film specification such as density difference of the wafer put to etching processing and the density distribution of reaction products in the vacuum chamber.

5. A vacuum processing apparatus according to claim 1, wherein the electrostatic adsorption bias distribution is controlled accurately and uniformly in regions divided into a plurality of portions such as a first sample table block for the central portion of the wafer and a second sample table block for the outer circumference of the wafer in a plurality of sample table blocks divided from the sample table circumferentially, that is, coaxially or radially into a plurality of portions each of an independent structure, conforming the device film specification such as density difference of the wafer put to etching processing and-the density distribution of reaction products in the vacuum chamber.

6. A vacuum processing apparatus according to claim 1, wherein the distribution of reaction products in the plane of the wafer placed on the sample table is made uniform, in a case where the reaction products in the vacuum chamber are in such a state that the density thereof is higher in the central portion of the wafer and the density thereof is lower in the outer circumference for the wafer, by controlling the temperature of the plurality of divided sample table blocks such that the temperature of the first sample table block for the outer circumference of the wafer is lower than that of the second sample table block for the central portion of the wafer.

7. A vacuum processing apparatus according to claim 1, wherein the ion distribution in the wafer plane of the wafer placed on the sample table is made uniform, in a case where the state of ions in the vacuum chamber is such that the density thereof is higher in the central portion of the wafer and the density thereof is lower in the outer circumference of the wafer, by controlling the RF bias for the plurality of divided sample table blocks such that the RF bias of the first sample table block for the outer circumference of the wafer is higher than that of the second sample table block for the central portion of the wafer.

8. A vacuum processing apparatus according to claim 1, wherein the distribution of the pressure at the rear face of the wafer placed on the sample table is made uniform, in a case where the pressure at the rear face of the wafer due to the heat conduction gas in the vacuum chamber is higher for the central portion of the sample and lower for the outer circumference of the sample by controlling the electrostatic adsorption bias for the plurality of divided sample tables such that the electrostatic adsorption bias of the first sample table block for the outer circumference of the wafer is higher than that of the second sample table block for the central portion of the wafer.

9. A vacuum processing apparatus, wherein the distribution of the reaction products, the ion distribution, and the distribution of the pressure at the rear face of the wafer in the plane of the wafer placed on the same table are made uniform by controlling the temperature, the RF bias, and the electrostatic adsorption bias for the plurality of divided sample table blocks in the vacuum chamber by the process conditions of the wafer according to claim 6.

10. A vacuum processing apparatus, wherein the distribution of the reaction products, the ion distribution, and the distribution of the pressure at the rear face of the wafer in the plane of the wafer placed on the same table are made uniform by controlling the temperature, the RF bias, and the electrostatic adsorption bias for the plurality of divided sample table blocks in the vacuum chamber by the process conditions of the wafer according to claim 7.

11. A vacuum processing apparatus, wherein the distribution of the reaction products, the ion distribution, and the distribution of the pressure at the rear face of the wafer in the plane of the wafer placed on the same table are made uniform by controlling the temperature, the RF bias, and the electrostatic adsorption bias for the plurality of divided sample table blocks in the vacuum chamber by the process conditions of the wafer according to claim 8.
